(19) United States
(12) Patent Application Publication
(10) Pub. No.: US 2026/0243828 A1
(43) Pub. Date: Aug. 20, 2026

(54) SYSTEM AND METHOD FOR FAULT DIAGNOSIS FOR CASCADED H-BRIDGE (CHB) CONVERTER BASED SWITCHED RELUCTANCE MOTOR (SRM) DRIVE SYSTEMS

(71) Applicant: ENEDYM INC., Hamilton (CA)

(72) Inventors: Nasir Ali, Hamilton (CA); Mehdi Narimani, Oakville (CA)

(21) Appl. No.: 19/544,282

(22) Filed: Feb. 19, 2026

Related U.S. Application Data
(60) Provisional application No. 63/760,337, filed on Feb. 19, 2025.

(51) Int. Cl. G01R 31/327; H02H 7/122; H02P 25/092

(52) U.S. Cl. CPC G01R 31/3275; H02H 7/1225; H02P 25/092

(57) ABSTRACT

Embodiments herein generally relate to systems and methods for identifying and locating one or more fault conditions in a cascaded H-bridge (CHB) converter for driving a switched reluctance motor (SRM), the SRM including a predetermined number of phases (m) and the CHB converter including a plurality of cells arranged into m phase legs, each phase leg including a predetermined number (n) of cells cascaded in series, where n≥1, and where each phase leg corresponds to a respective phase winding of the SRM, each cell including a plurality of switching elements and a corresponding dc-link, and a controller configured to selectively control the switching elements of the cascaded cells of each phase leg to produce, at an output of the corresponding phase leg, a plurality of discrete phase voltage levels for operating the SRM in a plurality of operating modes, where the number of discrete phase voltage levels provided by each phase leg equals 2n+1. The method includes monitoring, for a selected phase leg, a fundamental phase current, determining, from the monitored current, a deviation indicative of a fault condition, injecting complementary high-frequency (HF) diagnostic pulses into switching elements of different cells of the selected phase leg, extracting a pulse-induced HF current component from the measured phase current, determining a fault variable based on the extracted HF component, and determining, from the fault variable, a location of a faulty cell within the selected phase leg.

### CROSS-REFERENCE TO RELATED APPLICATION(S)

This application claims the benefit of U.S. Provisional Patent Application No. 63/760,337, filed Feb. 19, 2025, entitled “Phase-Voltage Diagnostic Scheme for Power Switch Faults in CHB-Fed Fault-Tolerant SRM Drives”. The contents of the U.S. Provisional Patent Application No. 63/760,337 are hereby incorporated herein by reference in its entirety.

### FIELD

The present disclosure generally relates to systems and methods for identifying and locating faults in a switched reluctance motor (SRM) drive system, and more particularly, to systems and methods for identifying and locating faults in power switches of a cascaded H-bridge (CHB) converter based SRM drive system.

### BACKGROUND

The following is not an admission that anything discussed below is part of the prior art or part of the common general knowledge of a person skilled in the art.

Switched reluctance motors (SRMs) are considered as an attractive alternative to the traditional permanent magnet machines for low to medium voltage industrial applications primarily due to the rare-earth free features. SRMs have been widely adopted for low voltage applications. However, their usage in higher voltage applications is limited due to the non-availability of scalable power converters. Cascaded H-bridge (CHB) converters help extend the benefits of SRMs beyond low voltage applications. The CHB converter has several advantages such as scalability, modularity, redundancy in switching states, and better output waveforms.

SRMs are free from permanent magnets, and the phase currents are unidirectional in SRM drives. The combination of CHB converters with SRMs offers several attractive advantages compared with other AC machines including cost-effectiveness and fault tolerance. More importantly, the SRMs can be effectively utilized for medium voltage (MV) industrial applications.

Nevertheless, the power switches in the converter are highly susceptible to different faults during operation and questions emerge as to the reliability and survivability of the drive system under harsh operating conditions. Studies on fault classification report that power switches in the power converter are the most fragile components, accounting for 35 to 38% of overall faults in the drive system. Power converter failures are categorized as open-circuit faults and short-circuit faults in power switches and power diodes. These faults are typically unrecoverable and may lead to the spreading of faults to other healthy components.

Accordingly, there is a need for a system and method for an effective and reliable fault diagnosis of CHB converter based SRM drive systems.

### SUMMARY

The following introduction is provided to introduce the reader to the more detailed discussion to follow. The introduction is not intended to limit or define any claimed or as yet unclaimed invention. One or more inventions may reside in any combination or sub-combination of the elements or process steps disclosed in any part of this document including its claims and figures.

In various embodiments disclosed herein, there is provided a system and method for real-time fault identification and localization in CHB converter based SRM drive systems by detecting variations in fundamental current to distinguish between open- and short-circuit faults.

In the various embodiments disclosed herein, a phase-shifted high-frequency (HF) pulse is injected into the power cells to pinpoint the faulty cell and defective switch, enabling early-stage detection within a single sampling period. Additionally, the system and method disclosed herein employ unipolar excitation, utilizing only two switches for current control while reserving the remaining two switches as fault-tolerant auxiliaries. For open-circuit faults, diagonal switch pairs are alternately excited, and if a pair fails, switching signals are redirected to maintain continuous operation without performance loss.

In the various embodiments disclosed herein, there is provided a system and method for short-circuit fault remediation by addressing single-switch faults without isolating the faulty cell through contactors. The system and method further identify multiple short-circuit faults and isolates the defective cell using a contactor to prevent further damage. This comprehensive fault diagnosis and control scheme ensures rapid detection, fault tolerance, and operational continuity, enhancing reliability and performance in CHB converter based SRM drive systems.

In accordance with one aspect, in various embodiments disclosed herein, there is provided a method for identifying and locating a fault condition in a cascaded H-bridge (CHB) converter system for driving a switched reluctance motor (SRM), the SRM comprising a predetermined number of phases (m), the CHB converter system comprising: a plurality of cells arranged into m phase legs, each phase leg comprising a predetermined number (n) of cells cascaded in series, where n≥1, and wherein each phase leg corresponds to a respective phase winding of the SRM, each cell comprising a plurality of switching elements and a corresponding dc-link, and a controller configured to selectively control the switching elements of the cascaded cells of each phase leg to produce, at an output of the corresponding phase leg, a plurality of discrete phase voltage levels for operating the SRM in a plurality of operating modes, wherein the number of discrete phase voltage levels provided by each phase leg equals 2n+1, and wherein the method comprises: monitoring, for a selected phase leg, using the controller, a fundamental phase current; determining, from the monitored current, a deviation indicative of a fault condition; injecting complementary high-frequency (HF) diagnostic pulses into switching elements of different cells of the selected phase leg; extracting a pulse-induced HF current component from the measured phase current; determining, using the controller, a fault variable based on the extracted HF component; and determining, from the fault variable, a location of a faulty cell within the selected phase leg.

In various embodiments, determining the deviation comprises classifying the fault condition as an open-circuit fault or a short-circuit fault based at least on the fundamental phase current and a predetermined reference current threshold.

In various embodiments, the fault condition is classified as an open-circuit fault if the fundamental phase current falls below the predetermined reference current threshold.

In various embodiments, the fault condition is classified as a short-circuit fault if the fundamental phase current increases above the predetermined reference current threshold.

In various embodiments, the method further comprises remediating the fault condition.

In various embodiments, when the number of cells, n, per phase is equal to 2, the number of discrete phase voltage levels for each phase is 5.

In various embodiments, determining the location of the faulty cell comprises determining a short-circuit fault condition in an upper cell when, during positive excitation, the fault variable is less than zero.

In various embodiments, determining the location of the faulty cell comprises determining a short-circuit fault condition in a lower cell when, during positive excitation, the fault variable is greater than zero.

In various embodiments, determining the location of the faulty cell comprises determining a short-circuit fault condition in both an upper cell and a lower cell when, during positive excitation, the fault variable is approximately equal to zero.

In various embodiments, determining the location of the faulty cell comprises determining an open-circuit fault condition in an upper cell when the fundamental phase current is greater than an open-circuit current and the fault variable is less than zero.

In various embodiments, determining the location of the faulty cell comprises determining an open-circuit fault condition in a lower cell when the fundamental phase current is greater than an open-circuit current and the fault variable is greater than zero.

In accordance with one aspect, in various embodiments disclosed herein, there is provided a system for identifying and locating a fault condition in a cascaded H-bridge (CHB) converter system for driving a switched reluctance motor (SRM), the SRM comprising a predetermined number of phases (m), the system comprising: a plurality of cells arranged into m phase legs, each phase leg comprising a predetermined number (n) of cells cascaded in series, where n≥1, and wherein each phase leg corresponds to a respective phase winding of the SRM, each cell comprising a plurality of switching elements and a corresponding dc-link, and a controller configured to selectively control the switching elements of the cascaded cells of each phase leg to produce, at an output of the corresponding phase leg, a plurality of discrete phase voltage levels for operating the SRM in a plurality of operating modes, wherein the number of discrete phase voltage levels provided by each phase leg equals 2n+1, wherein the controller is further configured to: monitor, for a selected phase leg, a fundamental phase current; determine, from the monitored current, a deviation indicative of a fault condition; inject complementary high-frequency (HF) diagnostic pulses into switching elements of different cells of the selected phase leg; extract a pulse-induced HF current component from the measured phase current; determine a fault variable based on the extracted HF component; and determine, from the fault variable, a location of a faulty cell within the selected phase leg.

In various embodiments, the controller is configured to determine the deviation by classifying the fault condition as an open-circuit fault or a short-circuit fault based at least on the fundamental phase current and a predetermined reference current threshold.

In various embodiments, the fault condition is classified as an open-circuit fault if the fundamental phase current falls below the predetermined reference current threshold.

In various embodiments, the fault condition is classified as a short-circuit fault if the fundamental phase current increases above the predetermined reference current threshold.

In various embodiments, the controller is further configured to remediate the fault condition.

In various embodiments, when the number of cells, n, per phase is equal to 2, the number of discrete phase voltage levels for each phase is 5.

In various embodiments, the controller is configured to: identify a short-circuit fault condition in an upper cell when, during positive excitation, the fault variable is less than zero, and identify a short-circuit fault condition in a lower cell when, during positive excitation, the fault variable is greater than zero.

In various embodiments, the controller is configured to identify a short-circuit fault condition in both an upper cell and a lower cell when, during positive excitation, the fault variable is approximately equal to zero.

In various embodiments, the controller is configured to: identify an open-circuit fault condition in an upper cell when the fundamental phase current is greater than an open-circuit current and the fault variable is less than zero, and identify an open-circuit fault condition in a lower cell when the fundamental phase current is greater than an open-circuit current and the fault variable is greater than zero.

Other features and advantages of the present application will become apparent from the following detailed description. It should be understood, however, that the detailed description and the specific examples, while indicating embodiments of the application, are given by way of illustration only and the scope of the claims should not be limited by these embodiments but should be given the broadest interpretation consistent with the description as a whole.

### BRIEF DESCRIPTION OF THE DRAWINGS

For a better understanding of the embodiments described herein and to show more clearly how they may be carried into effect, reference will now be made, by way of example only, to the accompanying drawings which show at least one exemplary embodiment, and in which:

FIG. 1 is a schematic diagram of a 2n+1 level cascaded H-bridge (CHB) converter for SRM drives, in accordance with an example.

FIG. 2 is a schematic diagram of a five-level CHB for a three-phase SRM, in accordance with an example.

FIG. 3 is a graph showing simulation waveforms of a CHB converter based SRM drive operating under normal conditions, in accordance with an example.

FIG. 4A is a schematic diagram of a CHB converter for SRM drive with an open-circuit fault condition in an upper switch in a first cell, in accordance with an example.

FIG. 4B is a schematic diagram of a CHB converter for SRM drive with an open-circuit fault condition in a lower switch in a first cell, in accordance with an example.

FIG. 4C is a schematic diagram of a CHB converter for SRM drive with an open-circuit fault condition in a lower switch in a second cell, in accordance with an example.

FIG. 5 is a process for fault diagnosis and tolerance control of a CHB converter based SRM drive, in accordance with an example.

FIG. 6 is a graph showing simulation waveforms of a CHB converter based SRM drive operating under a short-circuit fault condition, in accordance with an example.

FIG. 7 is a graph showing simulation waveforms of a CHB converter based SRM drive operating under an open-circuit fault condition, in accordance with an example.

FIG. 8 is a block diagram for filtering HF current components in a CHB converter based SRM drive operating under a fault condition, in accordance with an example.

FIG. 9 is a flowchart for fault diagnosis and tolerance control of a CHB converter based SRM drive under short-circuit fault conditions, in accordance with an example.

FIG. 10 is a flowchart for fault diagnosis and tolerance control of a CHB converter based SRM drive under open-circuit fault conditions, in accordance with an example.

FIG. 11 is a graph showing simulation waveforms of a CHB converter for SRM drive operating with an open-circuit fault condition in an upper cell, in accordance with an example.

FIG. 12 is a graph showing simulation waveforms of a CHB converter for SRM drive operating with an open-circuit fault condition in a lower cell, in accordance with an example.

FIG. 13 is a graph showing simulation waveforms of a CHB converter for SRM drive operating with a short-circuit fault condition in a lower cell, in accordance with an example.

FIG. 14 is a graph showing simulation waveforms of a CHB converter for SRM drive operating with a short-circuit fault condition in an upper cell, in accordance with an example.

### DESCRIPTION OF VARIOUS EMBODIMENTS

Various embodiments in accordance with the teachings herein will be described below to provide an example of at least one embodiment of the claimed subject matter. No embodiment described herein limits any claimed subject matter. The claimed subject matter is not limited to devices, systems or methods having all of the features of any one of the devices, systems or methods described below or to features common to multiple or all of the devices, systems or methods described herein. It is possible that there may be a device, system or method described herein that is not an embodiment of any claimed subject matter. Any subject matter that is described herein that is not claimed in this document may be the subject matter of another protective instrument, for example, a continuing patent application, and the applicants, inventors or owners do not intend to abandon, disclaim or dedicate to the public any such subject matter by its disclosure in this document.

For simplicity and clarity of illustration, reference numerals may be repeated among the figures to indicate corresponding or analogous elements. In addition, numerous specific details are set forth in order to provide a thorough understanding of the subject matter described herein. However, it will be understood by those of ordinary skill in the art that the subject matter described herein may be practiced without these specific details. In other instances, well-known methods, procedures and components have not been described in detail so as not to obscure the subject matter described herein. The description is not to be considered as limiting the scope of the subject matter described herein.

It should also be noted that the terms “coupled” or “coupling” as used herein can have several different meanings depending in the context in which these terms are used. For example, the terms coupled or coupling can have a mechanical, fluidic or electrical connotation. For example, as used herein, the terms coupled or coupling can indicate that two elements or devices can be directly connected to one another or connected to one another through one or more intermediate elements or devices via an electrical or magnetic signal, electrical connection, an electrical element or a mechanical element depending on the particular context. Furthermore, coupled electrical elements may send and/or receive data.

In understanding the scope of the present disclosure, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. The term “consisting” and its derivatives, as used herein, are intended to be closed terms that specify the presence of the stated features, elements, components, groups, integers, and/or steps, but exclude the presence of other unstated features, elements, components, groups, integers and/or steps. The term “consisting essentially of”, as used herein, is intended to specify the presence of the stated features, elements, components, groups, integers, and/or steps as well as those that do not materially affect the basic and novel characteristic(s) of features, elements, components, groups, integers, and/or steps.

It should also be noted that, as used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof. In effect, this term means that “at least one of” or “one or more” of the listed items is used or present.

Terms of degree such as “substantially”, “about” and “approximately” as used herein mean a reasonable amount of deviation of the modified term such that the end result is not significantly changed. These terms of degree should be construed as including a deviation of at least ±5% of the modified term if this deviation would not negate the meaning of the word it modifies. In addition, all ranges given herein include the end of the ranges and also any intermediate range points, whether explicitly stated or not.

In embodiments comprising an “additional” or “second” component, the second component as used herein is chemically different from the other components or first component. A “third” component is different from the other, first, and second components, and further enumerated or “additional” components are similarly different.

These terms of degree may also be construed as including a deviation of the modified term, such as by 1%, 2%, 5% or 10%, for example, if this deviation does not negate the meaning of the term it modifies.

Furthermore, the recitation of numerical ranges by endpoints herein includes all numbers and fractions subsumed within that range (e.g. 1 to 5 includes 1, 1.5, 2, 2.75, 3, 3.90, 4, and 5). It is also to be understood that all numbers and fractions thereof are presumed to be modified by the term “about” which means a variation of up to a certain amount of the number to which reference is being made if the end result is not significantly changed, such as 1%, 2%, 5%, or 10%, for example.

Reference throughout this specification to “one embodiment”, “an embodiment”, “at least one embodiment” or “some embodiments” means that one or more particular features, structures, or characteristics may be combined in any suitable manner in one or more embodiments, unless otherwise specified to be not combinable or to be alternative options.

As used in this specification and the appended claims, the singular forms “a,” “an,” and “the” include plural referents unless the content clearly dictates otherwise. It should also be noted that the term “or” is generally employed in its broadest sense, that is, as meaning “and/or” unless the content clearly dictates otherwise.

Similarly, throughout this specification and the appended claims the term “communicative” as in “communicative pathway,” “communicative coupling,” and in variants such as “communicatively coupled,” is generally used to refer to any engineered arrangement for transferring and/or exchanging information. Exemplary communicative pathways include, but are not limited to, electrically conductive pathways (e.g., electrically conductive wires, electrically conductive traces), magnetic pathways (e.g., magnetic media), optical pathways (e.g., optical fiber), electromagnetically radiative pathways (e.g., radio waves), or any combination thereof. Exemplary communicative couplings include, but are not limited to, electrical couplings, magnetic couplings, optical couplings, radio couplings, or any combination thereof.

Throughout this specification and the appended claims, infinitive verb forms are often used. Examples include, without limitation: “to detect,” “to provide,” “to transmit,” “to communicate,” “to process,” “to route,” and the like. Unless the specific context requires otherwise, such infinitive verb forms are used in an open, inclusive sense, that is as “to, at least, detect,” to, at least, provide,” “to, at least, transmit,” and so on.

The abbreviation, “e.g.” is derived from the Latin exempli gratia and is used herein to indicate a non-limiting example. Thus, the abbreviation “e.g.” is synonymous with the term “for example.” The word “or” is intended to include “and” unless the context clearly indicates otherwise.

It will be understood that any component defined herein as being included may be explicitly excluded by way of proviso or negative limitation, such as any specific compounds or method steps, whether implicitly or explicitly defined herein.

The existing diagnostic schemes for cascaded H-bridge (CHB) converters can be categorized into model-based, hardware-based, and feature-based approaches. The hardware-based approaches include additional sensors and healthy gate drivers. They may be useful for the detection of open-circuit faults with relatively lower detection delay. However, they monitor the gate signals and if the open-circuit fault is caused by the faulty gate driver, the diagnostic scheme is invalid. Similarly, most of the feature based diagnostic schemes normally require high-bandwidth current and voltage sensors thereby increasing the cost and complexity of the system. The model based diagnostic methods, in general, do not require additional sensors. However, this is achieved at the cost of higher detection delay and less robustness under dynamic conditions. Fault diagnosis in SRM drives has been extensively studied in the field. The studies mostly focus on the standard two-level AHB converter.

In various embodiments disclosed herein, there is provided a system and method for real-time fault identification and localization in CHB converter based SRM drive systems. In some embodiments, variations in fundamental current are used to distinguish between open- and short-circuit faults.

In the various embodiments disclosed herein, the detection and remediation of these typical faults involve three steps, including identifying the fault type, such as, for example, whether it is an open-circuit or a short-circuit fault, localizing the faulty power cell and remediating the detected fault. The various embodiments disclosed herein can effectively and reliably identify, localize, and remediate power switch faults in each H-bridge cell without requiring additional sensors, which is a key limitation of conventional topologies.

In the various embodiments disclosed herein, a high-frequency (HF) pulse is injected into the power switches, and the resulting HF current is extracted to localize the faulty power cell and, in some embodiments, defective switch. The transient nature of the HF pulse has no significant negative effect on the drive system. Furthermore, the illustrated embodiments enable early-stage detection of the faults, such as, within a single sampling period.

Additionally, the system and method disclosed herein employ unipolar excitation, utilizing only two switches for current control while reserving the remaining two switches as fault-tolerant auxiliaries. For open-circuit faults, diagonal switch pairs are alternately excited, and if a pair fails, switching signals are redirected to maintain continuous operation without performance loss.

The illustrated embodiments are cost-effective, simple, and robust for integration into the motor's controller for online diagnosis. Moreover, the illustrated embodiments are independent of motor parameters, making it universal for SRMs with any phase number or pole configurations.

Furthermore, in the various embodiments disclosed herein, there is also provided a system and method for short-circuit fault remediation by addressing single-switch faults without isolating the faulty cell through contactors. The system and method further identify multiple short-circuit faults and isolate the defective cell using a contactor to prevent further damage. This comprehensive fault diagnosis and control scheme ensures rapid detection, fault tolerance, and operational continuity, enhancing reliability and performance in CHB converter based SRM drive systems.

In some embodiments, the immediate application of this invention lies in heavy industries that require megawatt-level power, such as pipeline pumps in the petrochemical industry, fans in the cement industry, pumps in water pumping stations, and steel rolling mills in the metals industry, etc. These industries can benefit from the improved reliability of the SRM drive system through the illustrated embodiments. By integrating the developed diagnosis and tolerant control algorithms, the medium voltage SRM drive system can become more robust, and the immediate detection of failures can allow for timely maintenance or repairs, minimizing downtime and associated costs.

### CHB Converter Based SRM Drive Control Under Normal Operation

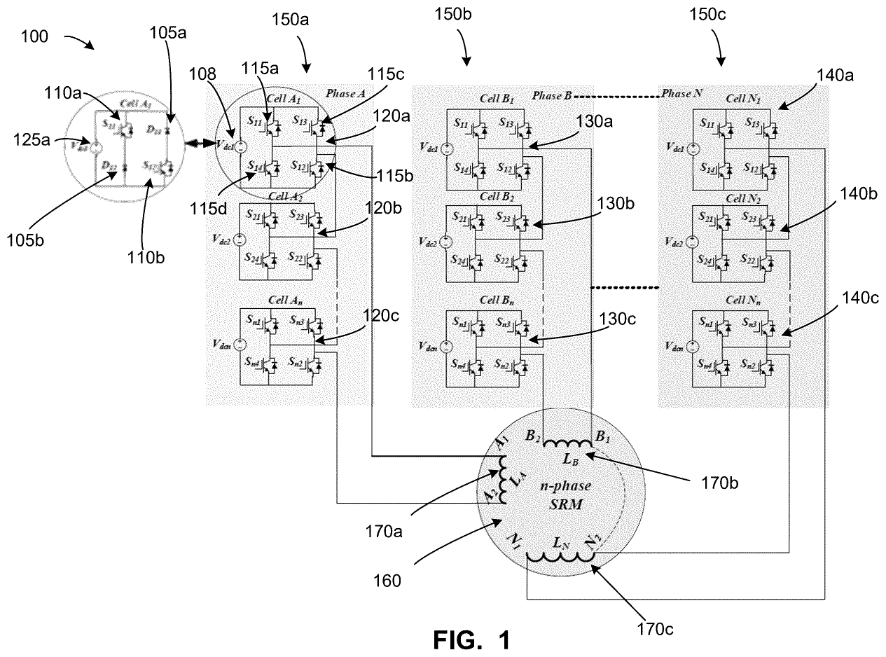

Reference is made to FIG. 1, which illustrates a schematic view of a power converter 100 for a SRM drive, in accordance with an example embodiment. In the illustrated embodiment, power converter 100 shows a 2n+1-level CHB topology, which comprises n-cells per phase for driving an m-phase SRM. In the disclosure herein, ‘n’ represents the number of cells and ‘m’ represents the number of phases of the SRM.

As shown, the topology 100 comprises a m-phase SRM 160. The illustrated SRM 160 is shown to have a first phase winding 170a, a second phase winding 170b, . . . , and an m-th phase winding 170c, corresponding to the first, second, and m-th phases of SRM 160. Each phase leg of the SRM drive comprises ‘n’ cells cascaded together. For example, the first phase leg 150a comprises a first cell 120a, a second cell 120b and a n-th cell 120c. Similarly, the second phase leg 150b comprises a corresponding first cell 130a, a second cell 130b and a n-th cell 130c. The M-th phase leg 150c comprises a corresponding first cell 140a, a second cell 140b and a n-th cell 140c.

In various embodiments, each of the ‘n’ cells per phase, i.e. cells 120a-c, 130a-c and 140a-c, contains a four-pack switch module in a H-bridge configuration. For example, cell 120a comprises a first switch 115a, a second switch 115b, a third switch 115c and a fourth switch 115d, and dc-link 108 connected in parallel to the four-pack switch module.

In some other embodiments, one or more phase legs 150a, 150b and 150c comprise cell 125a instead of 120a-c, 130a-c and/or 140a-c. Cell 125a comprises a first switch 110a, a second switch 110b, a first diode 105a and a second diode 105b, where the two switches and diodes are connected in an asymmetric half-bridge configuration. However, such a configuration may offer less fault-tolerance and may be more expensive compared to four-switched modular structure discussed above.

In the illustrated embodiment, multilevel voltages can be generated by cascading the power cells. The number of power cells and the desired number of output voltage levels have the relation of 2n+1, where ‘n’ refers to the number of cells per phase and ‘2n+1’ represents the number of voltage levels.

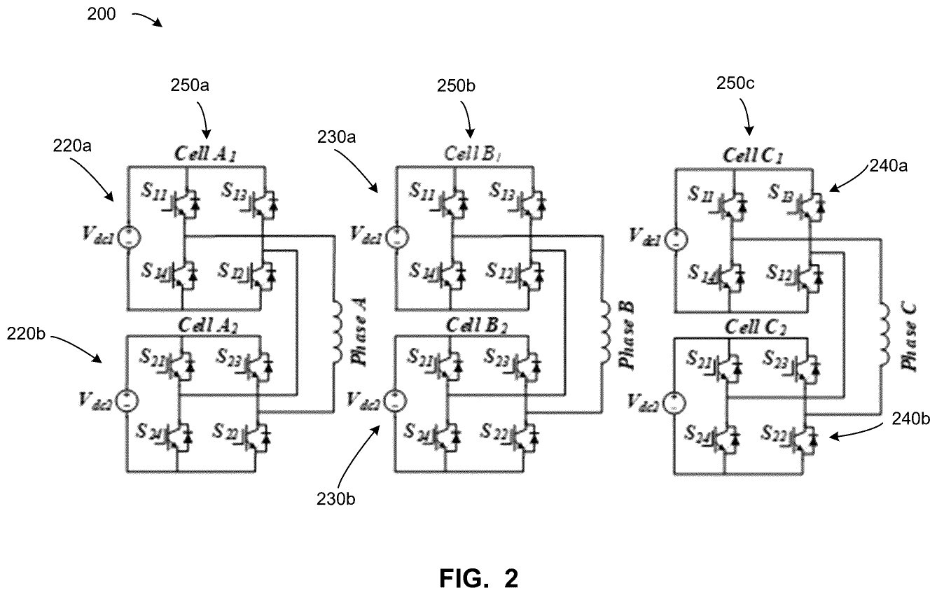

Reference is next made to FIG. 2, which illustrates a schematic view of a power converter 200 for a SRM drive, in accordance with an example embodiment. In particular, FIG. 2 shows a five-level CHB converter (i.e., provides 5 voltage levels), with each phase including two power cells. As shown, the first phase leg 250a comprises a first cell 220a and a second cell 220b. The second phase leg 250b comprises a first cell 230a and a second cell 230b. The third phase leg 250c comprises a first cell 240a and a second cell 240b.

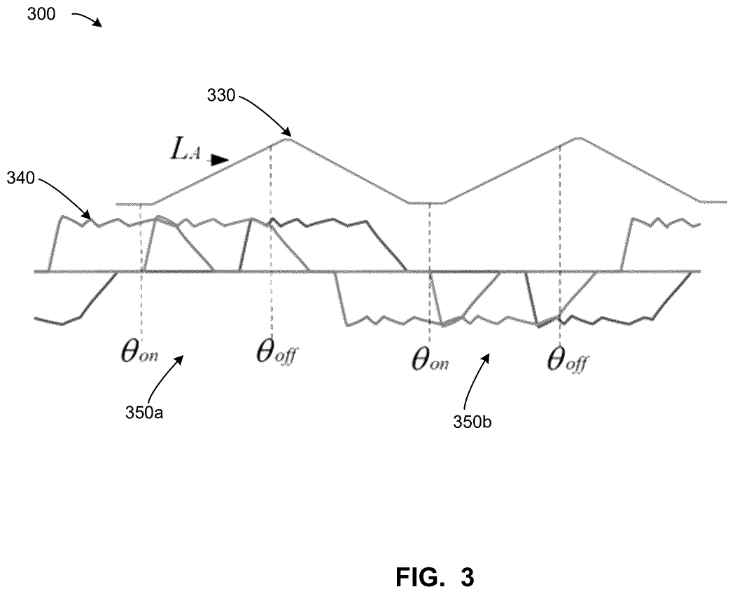

Reference is next made to FIG. 3, which illustrates example simulation waveforms 300 in accordance with an example embodiment. In particular, waveforms 300 include a first waveform 330 corresponding to phase inductance and fourth waveform 340 corresponding to a phase current, under soft-switching operation of the CHB converter. FIG. 3 shows the simulation waveforms 300 over two fundamental electrical periods, namely the first electrical period 350a and the second electrical period 350b.

Traditionally, the current direction in SRMs is unidirectional. With the CHB converter, the SRM can be rotated with bipolar excitation as the output torque is independent of phase current direction in SRM drives. For instance, taking phase A as an example, during the positive excitation, a first switch of a first cell (S11), a second switch of the first cell (S12), a first switch of a second cell (S21) and a second switch of the second cell (S22) are involved for phase current control. During the negative excitation, as shown in FIG. 3, pulse-width modulation (PWM) signals are steered to a third switch of a first cell (S13), a fourth switch of the first cell (S14), a third switch of a second cell (S23), and a fourth switch of the second cell (S24).

During the inductance ascending region, one switch of the power cell keeps chopping whole the other switch remains closed in the phase turn-on region. For example, in the inductance ascending region, the first switch of the first cell (S11) in a phase leg keeps chopping, whereas the second switch of the first cell (S12) remains closed in the phase turn-on region.

The five-level CHB converter can generate five output voltages and the typical working modes to apply these voltages are illustrated in Table 1 and Table 2. Table 1 shows the switching signals, phase voltage and the corresponding mode of operations for positive excitation. Table 2 shows the relations for negative excitations.

TABLE 1
Switching signals and operation modes when
current flowing in positive direction.

| S₁₁ | S₁₂ | S₁₃ | S₁₄ | S₂₁ | S₂₂ | S₂₃ | S₂₄ | voltage | Working mode |
|---|---|---|---|---|---|---|---|---|---|
| 1 | 1 | 0 | 0 | 1 | 1 | 0 | 0 | V_{dc1} + V_{dc2} | magnetization |
| 1 | 1 | 0 | 0 | 0 | 1 | 0 | 0 | V_{dc} | |
| 0 | 1 | 0 | 0 | 1 | 1 | 0 | 0 | V_{dc} | |
| 0 | 1 | 0 | 0 | 0 | 1 | 0 | 0 | 0 | Freewheeling |
| 1 | 1 | 0 | 0 | 0 | 0 | 0 | 0 | 0 | |
| 0 | 1 | 0 | 0 | 0 | 0 | 0 | 0 | −V_{dc1} − V_{dc2} | |
| 0 | 0 | 0 | 0 | 0 | 1 | 0 | 0 | −V_{dc} | Demagnetization |
| 0 | 0 | 0 | 0 | 0 | 0 | 0 | 0 | −V_{dc1} − V_{dc2} | |

TABLE 2
Switching signals and operation modes when current
flowing in negative direction.

| S₁₁ | S₁₂ | S₁₃ | S₁₄ | S₂₁ | S₂₂ | S₂₃ | S₂₄ | voltage | Working mode |
|---|---|---|---|---|---|---|---|---|---|
| 0 | 0 | 1 | 1 | 0 | 0 | 1 | 1 | V_{dc1} + V_{dc2} | magnetization |
| 0 | 0 | 1 | 1 | 0 | 0 | 0 | 1 | V_{dc} | |
| 0 | 0 | 0 | 1 | 0 | 0 | 1 | 1 | V_{dc} | |
| 0 | 0 | 0 | 1 | 0 | 0 | 0 | 1 | 0 | Freewheeling |
| 0 | 0 | 1 | 1 | 0 | 0 | 0 | 0 | 0 | |
| 0 | 0 | 0 | 1 | 0 | 0 | 0 | 0 | −V_{dc} | Demagnetization |
| 0 | 0 | 0 | 0 | 0 | 0 | 0 | 1 | −V_{dc} | |
| 0 | 0 | 0 | 0 | 0 | 0 | 0 | 0 | −V_{dc1} − V_{dc2} | |

The CHB converter, such as CHB converter 200, is controlled through magnetization, freewheeling and demagnetization modes. In magnetization mode, a positive voltage is applied across the phase winding, which generates current and, thus, torque. The freewheeling mode with a zero-voltage is applied to control the fundamental current at the reference value during the phase conduction region. The outgoing phase is demagnetized through a negative voltage at the turn-off angle. Five voltage levels can be applied across the phase windings under both positive and negative excitations. Under normal operation, positive and negative excitations are adopted alternatively in the two consecutive turn-on regions by making full use of the switches, which may provide the advantage of averaging the heat dissipation.

### Failure Analysis in CHB Converter Based SRM Drives

### Open-Circuit Faults

When an open-circuit fault occurs in a power switch in CHB converter based SRM drive, such as the CHB converter 200 of FIG. 2, the affected power cell is disconnected from the dc-link. The faulty power cell goes into a zero-voltage mode and as a result, the output voltage is reduced by half in a five-level CHB.

The open-circuit fault might cause the fundamental current to decay below the reference current particularly at high-speed operations. At lower speed regions, an open-circuit fault in a cell may not produce a significant effect on SRM control as the remaining cells could produce the required torque. However, the electrical and thermal load on the remaining cells would increase. Therefore, there is a need for an immediate detection and isolation of fault conditions.

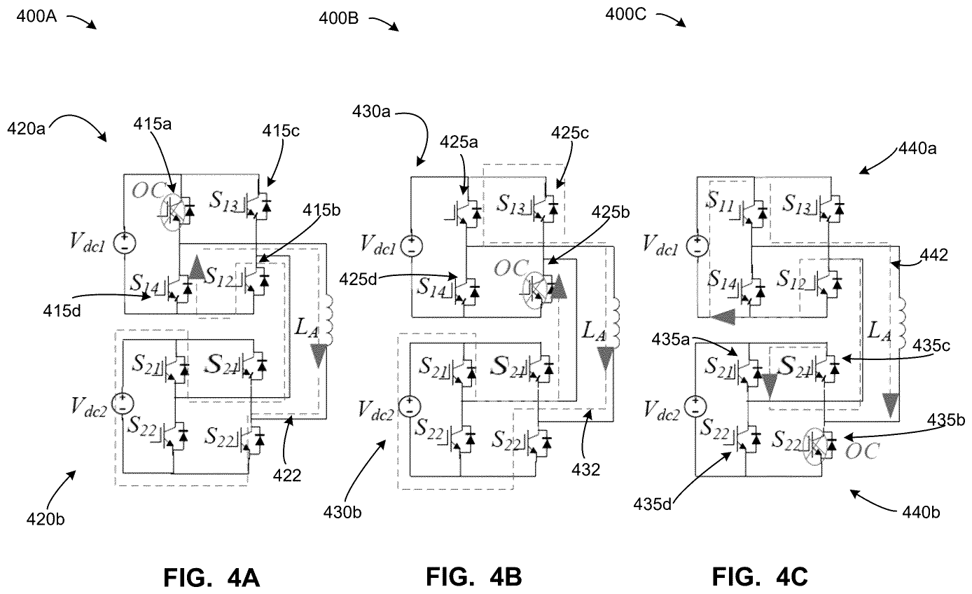

Reference is made to FIG. 4A-4C, which illustrate schematic views 400A-C, respectively, of a CHB converter based SRM drive, in accordance with an example embodiment. The CHB converter based SRM drive is analogous to CHB converter 200 of FIG. 2.

FIG. 4A illustrates the schematic view 400A of a power converter in an open-circuit fault condition, where the first switch 415a of the first cell 420a is open-circuited. The second switch 415b, the third switch 415c and the fourth switch 415d of the first cell 420a and all the switches of the second cell 420b are operating under normal conditions. FIG. 4A also illustrates the current path 422 during the magnetization mode under the open-circuit fault condition.

FIG. 4B illustrates the schematic view 400B of a power converter in an open-circuit fault condition, where the second switch 425b of the first cell 430a is open-circuited. The first switch 425a, the third switch 425c and the fourth switch 425d of the first cell 430a and all the switches of the second cell 430b are operating under normal conditions. The current path 432 during the magnetization mode under the open-circuit fault condition is also shown in FIG. 4B.

FIG. 4C illustrates the schematic view 400C of a power converter in an open-circuit fault condition, where the second switch 435b of the second cell 440b is open-circuited. The first switch 435a, the third switch 435c and the fourth switch 435d of the second cell 440b and all the switches of the first cell 440a are operating under normal conditions. The current path 442 during the magnetization mode under the open-circuit fault condition is also shown in FIG. 4C.

Since bipolar excitation is adopted during normal operation as shown in FIG. 3, an open-circuit fault in the first switch 415a of the first cell 420a, as shown in FIG. 4A, does not have an impact on the SRM during negative excitation i.e., when the third switch 415c (S₁₃), and the fourth switch (S₁₄) of the first cell 420a are turned on. The current direction is reversed to achieve fault-tolerance as explained in the later sections.

The various open-circuit failure cases and the effect on the working modes are illustrated in Table 3 and Table 4.

TABLE 3
Post fault magnetization modes under open-circuit
failures in a power cell during positive excitation

| S₁₁ | S₁₂ | S₁₃ | S₁₄ | S₂₁ | S₂₂ | S₂₃ | S₂₄ | Impact |
|---|---|---|---|---|---|---|---|---|
| OC | 1 | 0 | 0 | 1 | 1 | 0 | 0 | Output |
| | | | | | | | | voltage |
| | | | | | | | | reduction |
| 1 | OC | 0 | 0 | 1 | 1 | 0 | 0 | Output |
| | | | | | | | | voltage |
| | | | | | | | | reduction |
| OC | OC | 0 | 0 | 1 | 1 | 0 | 0 | Output |
| | | | | | | | | voltage |
| | | | | | | | | reduction |
| 1 | 1 | OC | 0 | 1 | 1 | 0 | 0 | No effect |
| 1 | 1 | 0 | OC | 1 | 1 | 0 | 0 | No effect |
| 1 | 1 | OC | OC | 1 | 1 | 0 | 0 | No effect |

TABLE 4
Post fault magnetization mode under open-circuit
failures in a power cell during negative excitation

| S₁₁ | S₁₂ | S₁₃ | S₁₄ | S₂₁ | S₂₂ | S₂₃ | S₂₄ | Impact |
|---|---|---|---|---|---|---|---|---|
| 0 | 0 | OC | 1 | 0 | 0 | 1 | 1 | Output |
| | | | | | | | | voltage |
| | | | | | | | | reduction |
| 0 | 0 | 1 | OC | 0 | 0 | 1 | 1 | Output |
| | | | | | | | | voltage |
| | | | | | | | | reduction |
| 0 | 0 | OC | OC | 0 | 0 | 1 | 1 | Output |
| | | | | | | | | voltage |
| | | | | | | | | reduction |
| OC | 0 | 1 | 1 | 0 | 0 | 1 | 1 | No effect |
| 0 | OC | 1 | 1 | 0 | 0 | 1 | 1 | No effect |
| OC | OC | 1 | 1 | 0 | 0 | 1 | 1 | No effect |

### Short-Circuit Faults

In case of a short-circuit fault in a power switch, the faulty cell is in zero-voltage loop (ZVL) during the phase turn-off region and as a result, it cannot supply demagnetization voltage to the faulty phase. The short-circuit faults, thus, limit the SRM's operation under high-speed region. In a five-level CHB, such as the CHB converter of FIG. 2, short-circuit faults in two diagonal switches in a power cell cause ZVL at the turn-off angle, potentially creating significant negative torque in the phase's turn-off region.

Since under normal operation, the SRM is excited bipolarly through the two opposite diagonal switches, a short-circuit fault in the first switch of a first cell (S₁₁) causes short-circuit of the dc-link if the fourth switch of the first cell (S₁₄) is turned on in the next fundamental period. Therefore, there is a need for diagnosis of the short-circuit fault in the same electrical period.

### Proposed Fault Diagnosis and Tolerant Control Schemes

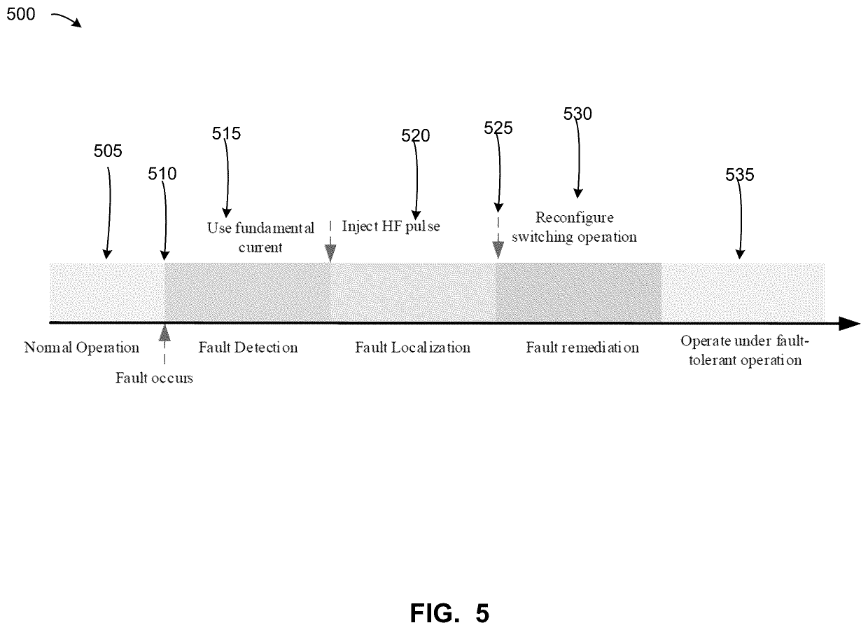

Reference is next made to FIG. 5, which illustrates a process 500 for fault diagnosis and tolerance control of a CHB converter based SRM drive, in accordance with an example embodiment. The CHB converter is analogous to CHB converter 200 of FIG. 2.

The process begins at step 505, where it is determined that the CHB converter is operating under normal conditions. At step 510, a fault condition occurs.

At step 515, the fundamental current and the switching signals of the CHB converter are analyzed to detect whether the fault condition in the CHB converter is an open-circuit fault or a short-circuit fault.

Under normal operation, the fundamental current is controlled at the reference current by using a typical PWM control scheme. When a short-circuit or an open-circuit fault appears in a power switch, the fundamental current behaves abnormally and can no longer be controlled at the reference limit. In case of a short-circuit fault, the phase current suddenly increases beyond the reference current. Similarly, in the case of an open-circuit fault, the fundamental current quickly drops below the reference current particularly at higher speed regions. Hence, when there is a sudden increase or decay in the fundamental current by a certain limit with respect to the reference current, a short- or an open-circuit fault is promptly determined, respectively.

At step 520, when the fault type is identified, complementary high-frequency (HF) pulses are injected into the power cells of the affected phase for fault localization, such as, for example, the first power cell (A1) and the second power cell (A2) of the same phase leg in CHB converter 200.

Consequently, the HF pulse on the healthy switches produces HF component to the phase current. For instance, if the unexpected current rise was caused by the short-circuit fault in a power switch in a first cell (A1), the pulse on the switches in the second cell (A2) produces HF current component. Similarly, when a fault affects the switches in the second cell (A2), the HF pulse injected to the switches in the first cell (A1) induces HF current component in the faulty phase.

Considering that an open- or a short-circuit fault occurs in a power switch of a first cell (A1) in phase A, the phase voltage can be regulated through the high-frequency (HF) pulses as

$${V}_{dc .} {S}_{HF} = {R}_{a} {i}_{a} + {L}_{a} ( θ , {i}_{a} ) \frac{{di}_{a}}{dt} + k ω {i}_{a} \qquad ( 1 )$$

where S_{HF} represents complementary pulses, which produce HF current to the fundamental current.

At step 525, the induced HF current is filtered, and fault variables are generated to locate the faulty power cells.

At step 530, two auxiliary switches per phase are used to reconfigure the power converter under failure conditions. Fault-tolerant reconfiguration is applied if one of the switches in a power cell is faulted. Therefore, localization of the faulty cell is essential, but localization of the individual faulty switch is not necessary. At 535, the converter operates under fault-tolerant conditions.

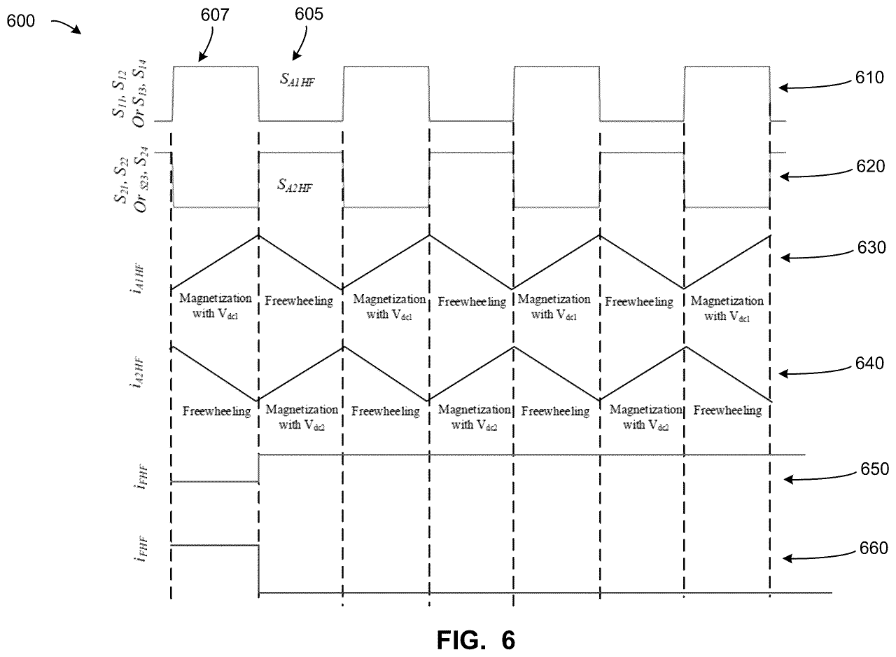

Reference is next made to FIG. 6, which illustrates example simulation waveforms 600 for a short-circuit fault condition in a CHB converter based SRM drive, such as, for example, CHB converter 200 of FIG. 2, in accordance with an example embodiment.

In particular, waveforms 600 include a first waveform 610 corresponding to HF pulse injection into a subset of switches (namely, the first (S₁₁) and the second (S₁₂) switches, or the third (S₁₃) and the fourth (S₁₄) switches) in the first cell, a second waveform 620 corresponding to HF pulse injection into a subset of switches (namely, the first (S₂₁) and the second (S₂₂) switches, or the third (S₂₃) and the fourth (S₂₄) switches) in the second cell, a third waveform 630 corresponding to HF current component in the first cell, a fourth waveform 640 corresponding to HF current component in the second cell, a fifth waveform 650 corresponding to a first fault variable represented by i_{FHF} used for locating the faulty power cell, and a sixth waveform 660 corresponding to a second fault variable represented by i_{FHF}.

As shown in FIG. 6, identical HF pulses are injected into both switches (either positive or negative excitation) of a cell (e.g., cell A1), while the HF pulses injected into the switches of the distinct cell (e.g., cell A2) are complementary. This is illustrated in waveforms 610 and 620, respectively.

The HF pulse injection is analyzed considering a short-circuit in the first cell (i.e., cell A1). In the illustrated embodiments, the complementary HF pulses are injected into the first (A1) and the second (A2) cells as soon as the short-circuit fault is detected.

The HF current generated by the HF pulses injected into the first cell (S_{A1HF}) is represented by i_{HFA1} in waveform 630, and the HF current generated by the HF pulses injected into the second cell (S_{A2HF}) is denoted by i_{HFA2} in waveform 640 in FIG. 6.

When S_{A2HF}=1 and S_{A1HF}=0, as shown in region 605:

$$\frac{{di}_{a}}{dt} = \frac{1}{L} ( {V}_{dc 2} - k ω {i}_{a} - {R}_{a} {i}_{a} ) > 0 \qquad ( 2 )$$

Under a short-circuit fault in cell A1, a HIGH state of HF pulse on the switches of the healthy cell, i.e. cell A2, magnetizes the faulty cell, i.e. cell A1, with dc-link voltage V_{dc2}, as shown by waveform 640 in region 605. A LOW state of the injected HF pulse on the healthy cell causes freewheeling as illustrated by equation (3) and shown by waveform 640 in region 607.

When S_{A2HF}=0 and S_{A1HF}=1, as shown in region 607:

$$\frac{{di}_{a}}{dt} = \frac{1}{L} ( - k ω {i}_{a} - {R}_{a} {i}_{a} ) < 0 \qquad ( 3 )$$

The magnetization and freewheeling of the faulty phase under HF pulse injection induces HF current in the faulty phase.

Similarly, if a short-circuit fault appears in the lower cell A2, analogous pattern results. However, in this case, the HF pulses on the power switches in A1 produce the induced HF current according to equations (4) and (5).

$$\begin{matrix}When {S}_{A 1 HF} = 1 and {S}_{A 2 HF} = 0 \\ \frac{{di}_{a}}{dt} = \frac{1}{L} ( {V}_{dc 1} - k ω {i}_{a} - {R}_{a} {i}_{a} ) > 0\end{matrix} \qquad ( 4 )$$

$$\begin{matrix}when {S}_{A 1 HF} = 0 and {S}_{A 2 HF} = 1 \\ \frac{{di}_{a}}{dt} = \frac{1}{L} ( - k ω {i}_{a} - {R}_{a} {i}_{a} ) < 0\end{matrix} \qquad ( 5 )$$

Unlike (2) and (3), magnetization and freewheeling are caused by the pulses on the first cell (A1), which is S_{A1HF}, as shown by waveform 630 in regions 607 and 605, respectively.

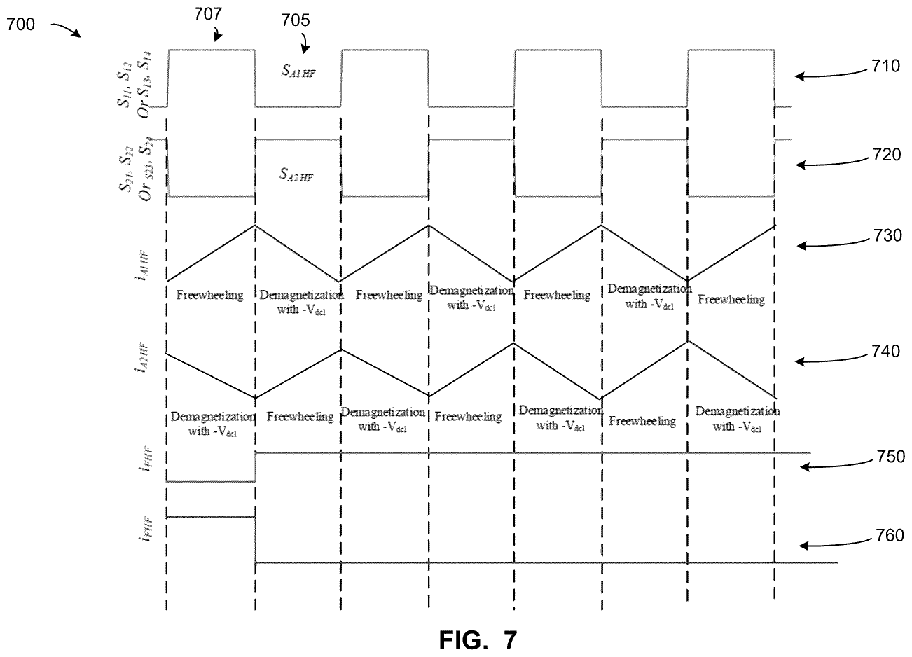

Reference is next made to FIG. 7, which illustrates example simulation waveforms 700 for an open-circuit fault condition in a CHB converter based SRM drive, such as, for example, CHB converter 200 of FIG. 2, in accordance with an example embodiment.

In particular, waveforms 700 include a first waveform 710 corresponding to HF pulse injection into a subset of switches (namely, the first (S₁₁) and the second (S₁₂) switches, or the third (S₁₃) and the fourth (S₁₄) switches) in the first cell, a second waveform 720 corresponding to HF pulse injection into a subset of switches (namely, the first (S₂₁) and the second (S₂₂) switches, or the third (S₂₃) and the fourth (S₂₄) switches) in the second cell, a third waveform 730 corresponding to HF current component in the first cell, a fourth waveform 740 corresponding to HF current component in the second cell, a fifth waveform 750 corresponding to a first fault variable and a sixth waveform 760 corresponding to a second fault variable.

In case of an open-circuit fault, the nature of the HF pulses is the same as illustrated in FIG. 6, but the operating modes are different. For instance, if an open-circuit fault appears in the first power cell (A1), S_{A2HF} produces HF currents through a series of freewheeling and demagnetization, as shown by waveform 740.

When S_{A1HF}=0 and S_{A2HF}=1, as shown in region 705

$$\frac{{di}_{a}}{dt} = \frac{1}{L} ( - k ω {i}_{a} - {R}_{a} {i}_{a} ) < 0 \qquad ( 6 )$$

With an open-circuit in the first cell (A1), a HIGH pulse on the second power cell (A2) causes zero voltage across the faulty phase and produces freewheeling mode, as shown in waveform 740 in region 705.

When S_{A1HF}=1 and S_{A2HF}=0, as shown in region 707

$$\frac{{di}_{a}}{dt} = \frac{1}{L} ( - {V}_{dc 2} - k ω {i}_{a} - {R}_{a} {i}_{a} ) < 0 \qquad ( 7 )$$

The zero-voltage under freewheeling when S_{A2HF}=1 slows down the current decay, while the negative voltage under demagnetization makes the current decay faster. This series of freewheeling and demagnetization by the pulses on the healthy switch produces current component similar to a short-circuit fault condition.

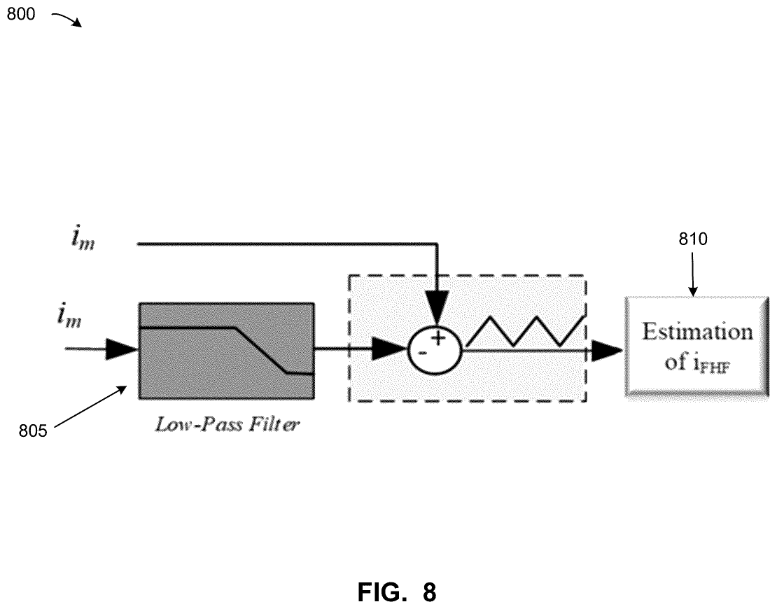

Reference is next made to FIG. 8, which illustrates a block diagram 800 of a low-pass filter circuit, in accordance with an example embodiment. To manipulate the current component produced by the HF pulse for online fault localization, the fundamental current is filtered through a low-pass filter 805 as shown in FIG. 8. The relationship between the voltage pulse, the induced HF current, and the filtered HF current component is illustrated in FIGS. 6 and 7. When the frequency of the injected pulses is sufficiently high and pulses are injected for a transient period, a linear change in the current can be obtained as illustrated in FIGS. 6 and 7.

In order to accurately locate the faulty cell, a fault variable 810 is derived based on the filtered current components shown in FIG. 6 and FIG. 7. The fault variable represented by i_{FHF} is used for locating the faulty power cell. In order to monitor i_{FHF}, the induced HF currents (i_{A1HF} and i_{A2HF}) shown in FIGS. 6 and 7, are detected at the rising and falling edges of S_{A1HF}.

$${i}_{FHF} = {i}_{HFn} - {i}_{HFn - 1} \qquad ( 8 )$$

where i_{HFn} is the current detected at the falling edge and i_{HFn-1} is the current detected at the previous rising edge.

It can be observed from FIG. 6 that at the rising edge of the HF pulse, the induced HF current component starts increasing due to the magnetization and reaches a maximum value at the falling edge and till the next rising edge the HF current reduces to the minimum value through freewheeling. FIG. 6 also shows that induced current i_{A1HF} is produced by S_{A1HF} and i_{A2HF} is produced by S_{A2HF}.

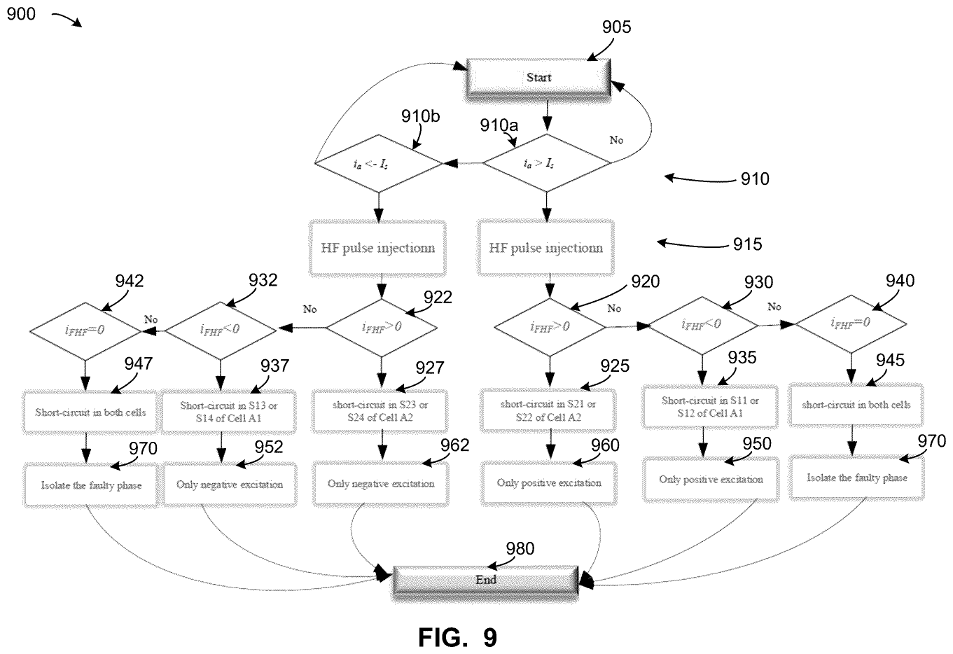

Reference is next made to FIG. 9, which illustrates a process 900 of fault diagnosis and tolerant control in a CHB converter based SRM drive system, in accordance with an example embodiment. In particular, process 900 pertains to a short-circuit fault condition in a power cell of a CHB converter, such as, for example, a first power cell A1 or a second power cell A2 of the CHB converter 200 of FIG. 2.

The process begins at step 905. At step 910, it is determined if the fault occurs during positive excitation (910a) or negative excitation (910b). Next, identical HF pulses are injected into the power cells at step 915.

If a short-circuit fault occurs in the first or the second switch in the first cell (i.e., S11 or S12 of cell A1) during the positive excitation, the injected pulse S_{A1HF} has no significant effect on the fundamental current, while S_{A2HF} produces the HF current component, i_{A2HF}. In this case, the fault variable i_{FHF} is expressed in accordance with equation (9):

$${i}_{FHF} < 0 \qquad ( 9 )$$

If the short-circuit fault occurs in the first or the second switch of the second cell (i.e., S21 or S22 of cell A2), the fault variable i_{FHF} turns a value greater than zero as

$${i}_{FHF} > 0 \qquad ( 10 )$$

As illustrated in FIG. 6, when the upper cell is faulted, the pulse on the lower cell produces the HF current component, while when the lower cell is faulted, the HF pulse on the upper cell produces the HF component. Therefore, once the fault is determined to be an open- or a short-circuit fault, the faulty cell is localized in a two HF pulse period by simply looking at i_{FHF}.

Accordingly, assuming the short-circuit fault occurs during the positive excitation, the process proceeds to step 920, where it is determined if the fault variable i_{FHF} has a value greater than 0. If so, the process proceeds to step 925, where it is determined that a short-circuit fault has occurred in the second cell (i.e., in the first S21 or the second S22 switch of the second cell A2).

If, at step 920, it is determined that the fault variable i_{FHF} does not have a value greater than 0, the process proceeds to step 930, where it is determined if the fault variable i_{FHF} has a value less than 0. If so, the process proceeds to step 935, where it is determined that a short-circuit fault has occurred in the first cell (i.e., in the first S11 or the second S12 switch of the first cell A1).

If, at step 930, it is determined that the fault variable i_{FHF} does not have a value less than 0, the process proceeds to step 940, where it is determined if the fault variable i_{FHF} has a value approximately equal to 0. If so, the process proceeds to step 945, where it is determined that the short-circuit condition has occurred in both cells (i.e. the first A1 and the second A2 cells).

Similarly, assuming the short-circuit fault is detected during the negative excitation, the process proceeds to step 922, where it is determined if the fault variable i_{FHF} has a value greater than 0. If so, the process proceeds to step 927, where it is determined that a short-circuit fault has occurred in the second cell (i.e., in the third S23 or the fourth S24 switch of the second cell A2).

If, at step 922, it is determined that the fault variable i_{FHF} does not have a value greater than 0, the process proceeds to step 932, where it is determined if the fault variable i_{FHF} has a value less than 0. If so, the process proceeds to step 937, where it is determined that a short-circuit fault has occurred in the first cell (i.e., in the third S13 or the fourth S14 switch of the first cell A1).

If, at step 932, it is determined that the fault variable i_{FHF} does not have a value less than 0, the process proceeds to step 942, where it is determined if the fault variable i_{FHF} has a value approximately equal to 0. If so, the process proceeds to step 947, where it is determined that the short-circuit condition has occurred in both cells (i.e. the first A1 and the second A2 cells).

As illustrated in FIG. 9, if the fault appears during the positive excitation and the fault is localized as a short-circuit in power cell A1 (S11 or S12), the process proceeds to step 950, where negative excitation in the next fundamental period is immediately stopped to avoid short-circuit of the dc-link through the first and the fourth switches (S11 and S14) or the third and the second switches (S13 and S12) of the first cell A1. The faulty cell is used to produce magnetization and freewheeling during the phase turn-on region. During the turn-off region, the faulty cell is in zero-voltage state to allow demagnetization of the phase through the healthy cell. Similarly, if the short-circuit fault is detected in the third or the fourth switches (S13 or S14) of the first cell A1 during the negative excitation, as soon as the fault is detected, the controller is stopped from applying positive excitation at step 952.

As further illustrated in FIG. 9, if the fault appears during the positive excitation and the fault is localized as a short-circuit in power cell A2 (S21 or S22), the process proceeds to step 960, where the controller is stopped from applying negative excitation. Similarly, if the fault appears during the negative excitation and the fault is localized as a short-circuit in power cell A2 (S23 or S24), the process proceeds to step 962, where the controller is stopped from applying positive excitation.

In the event a short-circuit condition is detected in both cells of a phase, whether during positive excitation (at 945) or negative excitation (947), the process proceeds to step 970, where the faulty phase is isolated. Th process ends at 980. Detecting the fault at the earliest stage is likely to provide the advantage of avoiding turning on both switches on the same phase leg.

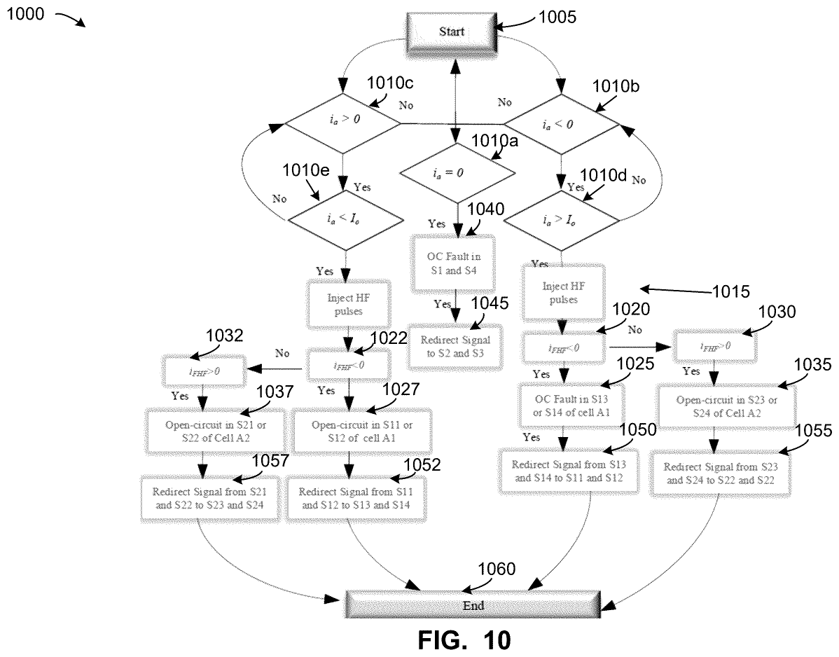

Reference is next made to FIG. 10, which illustrates a process 1000 of fault diagnosis and tolerant control in a CHB converter based SRM drive system, in accordance with an example embodiment. In particular, process 1000 pertains to an open-circuit fault condition in a power cell of a CHB converter, such as, for example, a first power cell A1 or a second power cell A2 of the CHB converter 200 of FIG. 2.

The process begins at step 1005. At step 1010, it is determined if the phase current (such as, for example, phase A current) is approximately equal to 0 (1010a), less than 0 (1010b) or greater than 0 (1010c).

If it is determined that the phase current is less than 0 at step 1010b, the process proceeds to step 1010d. If it is determined that the phase current is greater than 0 at step 1010c, the process proceeds to step 1010e.

At step 1010d, it is determined if the phase current is greater than open-circuit current, and at step 1010e, it is determined if the phase is current is less than open-circuit current to determine if the fault occurs during positive excitation or negative excitation. Next, identical HF pulses are injected into the power cells at step 1015.

Similar to the short-circuit fault, in case of an open-circuit fault in the first cell (A1), the HF pulse on the lower cell (A2), produces i_{A2HF} and at the falling edge of S_{A1HF}, the fault variable produces a negative i_{FHF} as

$${i}_{FHF} < 0 \qquad ( 11 )$$

When the open-circuit fault occurs in the second cell (A2), the HF component is produced by the pulses on the upper cell (A1), and thus the variable being calculated at the rising and falling edges of the pulses on the upper cell can be a higher value in accordance with equation (12)

$${i}_{FHF} > 0 \qquad ( 12 )$$

Accordingly, assuming the open-circuit fault occurs when the phase current is greater than the open-circuit current, the process proceeds to step 1020, where it is determined if the fault variable i_{FHF} has a value less than 0. If so, the process proceeds to step 1025, where it is determined that an open-circuit fault has occurred in the first cell (i.e., in the third S13 or the fourth S14 switch of the first cell A1).

If, at step 1020, it is determined that the fault variable i_{FHF} does not have a value less than 0, the process proceeds to step 1030, where it is determined if the fault variable i_{FHF} has a value greater than 0. If so, the process proceeds to step 1035, where it is determined that an open-circuit fault has occurred in the second cell (i.e., in the third S23 or the fourth S24 switch of the second cell A2).

Similarly, assuming the open-circuit fault is detected when the phase current is less than the open-circuit current, the process proceeds to step 1022, where it is determined if the fault variable i_{FHF} has a value less than 0. If so, the process proceeds to step 1027, where it is determined that an open-circuit fault has occurred in the first cell (i.e., in the first S11 or the second S12 switch of the first cell A1).

If, at step 1022, it is determined that the fault variable i_{FHF} does not have a value less than 0, the process proceeds to step 1032, where it is determined if the fault variable i_{FHF} has a value greater than 0. If so, the process proceeds to step 1037, where it is determined that an open-circuit fault has occurred in the second cell (i.e., in the first S21 or the second S22 switch of the second cell A2).

As illustrated in FIG. 10, in case of an open-circuit fault in one of the switches during either positive or negative excitations, the switching signals are directed to other healthy switches, and the fault is contained. For instance, if two diagonal switches S11 and S12 are open-circuited, the phase current is controllable through negative excitation.

As illustrated in FIG. 10, if the fault appears when the phase current is greater than the open-circuit current and the fault is localized as an open-circuit in power cell A1 (S13 or S14), the process proceeds to step 1050, where the signal is redirected from the third and the fourth switches (S13 and S14) to the first and the second switches (S11 and S12).

Similarly, if the open-circuit fault appears in power cell A2 (S23 or S24), as determined at step 1035, the process proceeds to step 1055, where the signal is redirected from the third and the fourth switches (S23 and S24) to the first and the second switches (S21 and S22).

As further illustrated in FIG. 10, if the fault when the phase current is less than the open-circuit current and the fault is localized as an open-circuit in power cell A1 (S11 or S12), the process proceeds to step 1052, where the signal is redirected from the first and the second switches (S11 and S12) to the third and the fourth switches (S13 and S14).

Similarly, if the open-circuit fault appears in power cell A2 (S21 or S22), as determined at step 1037, the process proceeds to step 1057, where the signal is redirected from the first and the second switches (S21 and S22) to the third and the fourth switches (S23 and S24).

If, at step 1010a, it is determined that the phase current is approximately equal to 0, the process proceeds to step 1040, where it is determined that there is an open-circuit fault in the first and the fourth switches. The process then proceeds to step 1045, where the signal is redirected from the first and the fourth switches to the second and the third switches. The process ends at step 1060.

### Simulation Validations

The diagnostic and tolerant control scheme disclosed herein was tested for a five-level CHB converter based SRM drive through extensive simulations in MATLAB/SIMULINK. Although the diagnosis and tolerance control process is tested for a case study of five-level CHB converter based SRM, it is understood that the diagnosis and tolerance control process can be extended to any level of voltage.

A three-phase SRM model was used to simulate the drive system. In order to detect the sudden rise and decay of the fundamental current under failure conditions, two thresholds were introduced. The thresholds for open-circuit and short-circuit faults are denoted by Iₒ and Iₛ, respectively. The thresholds are defined as the function of the reference current in equations (13) and (14).

$${I}_{0} = {k}_{0.} {i}_{ref} \qquad ( 13 )$$

$${I}_{s} = {k}_{s .} {i}_{ref} \qquad ( 14 )$$

where kₒ and kₛ are the co-efficient for the thresholds. For fast localization of the faults, 10 KHz frequency is selected for the HF pulses. Four failure scenarios are tested and presented herein.

### Diagnosis and Tolerant Control for Open-Circuit Faults

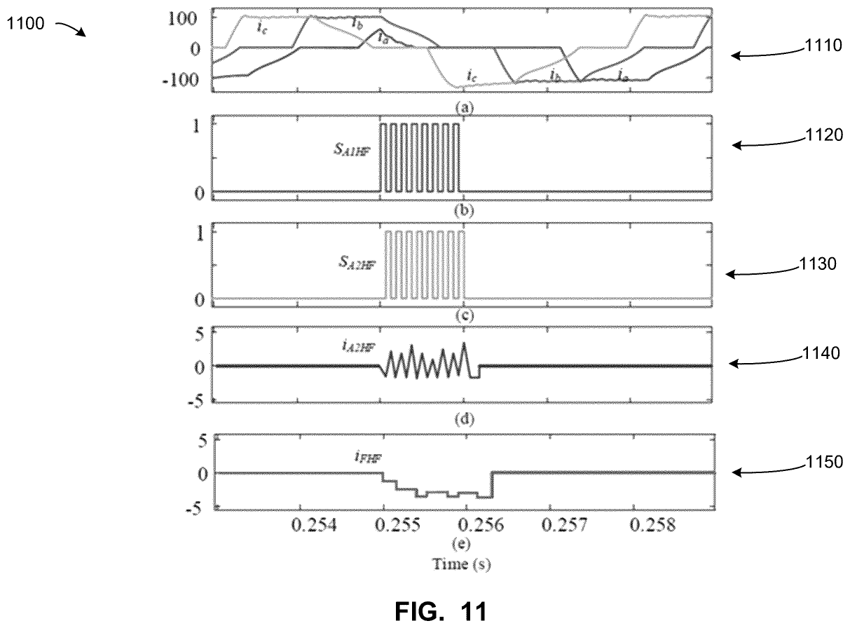

Reference is made to FIG. 11, which illustrates example simulation waveforms 1100 generated by testing the diagnosis and tolerant control disclosed herein for an open-circuit fault in the first cell (A1), in accordance with an example embodiment. In particular, the diagnosis and tolerance control process disclosed herein is adopted under an open-circuit fault in the first switch (S11) in the first cell at 83% of the rated speed.

Waveforms 1100 include a first waveform 1110 corresponding to three-phase currents, a second waveform 1120 corresponding to HF pulse injection into the first cell (A1), a third waveform 1130 corresponding to HF pulse injection into the second cell (A2), a fourth waveform 1140 corresponding to induced HF current and a fifth waveform 1150 corresponding to fault variable.

In accordance with the process illustrated in FIG. 10, as soon as an open-circuit fault is detected through the threshold Iₒ, complementary HF pulses are injected into the power cells, as shown in FIG. 11. The induced HF current is sampled and the fault variable i_{FHF} is calculated at the rising and falling edges of the HF pulse S_{A1HF} according to FIG. 7. As shown, the fault variable i_{FHF} turns to a negative value at the very first falling edge of S_{A1HF} denoting an open-circuit fault in the first power cell (A1) according to equation (11). Once the fault is located, tolerant procedures are adopted to sustain the machine's operation. The faulty phase operation is completely shifted to negative excitations. If an open-circuit fault occurs in the negative excitation modes, the healthy positive excitation helps to remediate the fault.

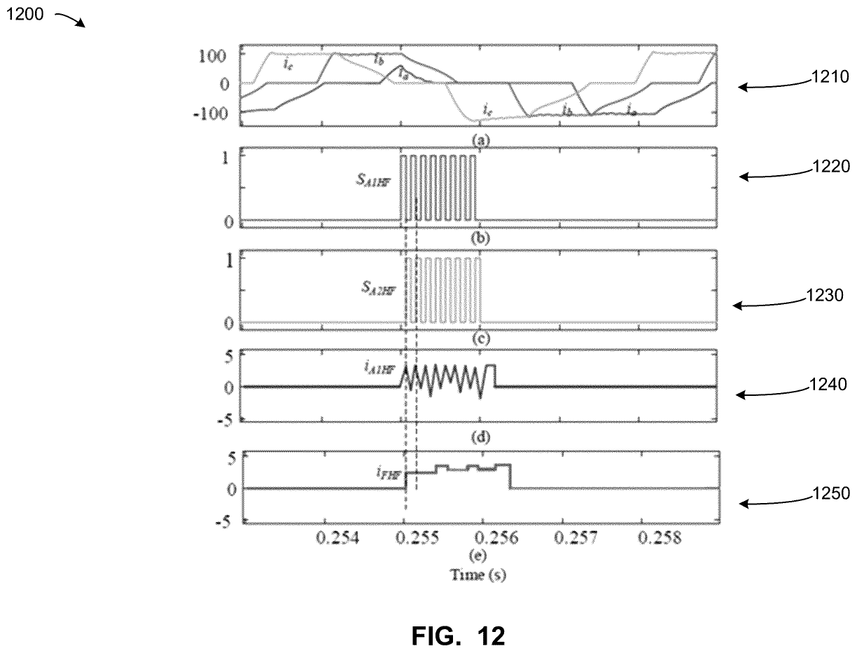

Reference is made to FIG. 12, which illustrates example simulation waveforms 1200 generated by testing the diagnosis and tolerant control disclosed herein for an open-circuit fault in the second cell (A2), which is a lower power cell, in accordance with an example embodiment. In particular, the diagnosis and tolerance control process disclosed herein is adopted under an open-circuit fault in the first switch (S21) in the second cell at 83% of the rated speed.

Waveforms 1200 include a first waveform 1210 corresponding to three-phase currents, a second waveform 1220 corresponding to HF pulse injection into the first cell (A1), a third waveform 1230 corresponding to HF pulse injection into the second cell (A2), a fourth waveform 1240 corresponding to induced HF current and a fifth waveform 1250 corresponding to fault variable.

Similar to FIG. 11, an open-circuit fault in a switch in the lower power cell A2 is introduced in FIG. 12. The same procedure is followed as in FIG. 11 to detect and locate the fault. In accordance with FIG. 10 and equations (11) and (12), I_{FHF} is positive in FIG. 12 representing an open-circuit fault in S21 or S22. When the fault is localized, the HF pulses are removed, and the switching signals are redirected to the negative excitation in phase A to retain the drive operation.

Under low-speed operating conditions, full-dc link voltage is, generally, not required for normal operations. This is mainly because of low induced voltage at lower speed regions. Consequently, if one of the power cells is disconnected due to an open-circuit fault, an evident fault feature is unlikely to be detected through the fundamental current as it will not decay below the threshold, Iₒ. Generally, a voltage sensor is utilized to measure the phase voltage and the comparison between the expected voltage and the actual voltage is used for fault diagnosis in such a situation. However, the illustrated embodiments provide the advantage of eliminating the need for voltage sensors, thereby reducing system cost and enabling a more efficient diagnostic scheme.

In a five-level CHB converter, V_{dc1} and V_{dc2} are alternatively applied for phase magnetization at lower speed regions where V_{dc1}+V_{dc2} is not essentially needed. In the illustrated embodiments, during the positive excitation, V_{dc1} is applied across the phase winding and during the negative excitation, V_{dc2} is used for phase magnetization. Therefore, if an open-circuit fault appears in the first cell A1, V_{dc1} is not available to magnetize the phase during the positive excitation. Under normal conditions, the second cell A2 should be in a zero-voltage state during positive excitation. However, due to an open-circuit fault in A1 during positive excitation, cell A2 will be in magnetization mode, which is a potential sign of an open-circuit fault in cell A1. The same phenomenon occurs when an open-circuit fault occurs in cell A2 during the negative excitation. Once the open-circuit fault is detected, the localization procedure disclosed herein is similar under all operating regions.

### Diagnosis and Tolerant Control for Short-Circuit Faults

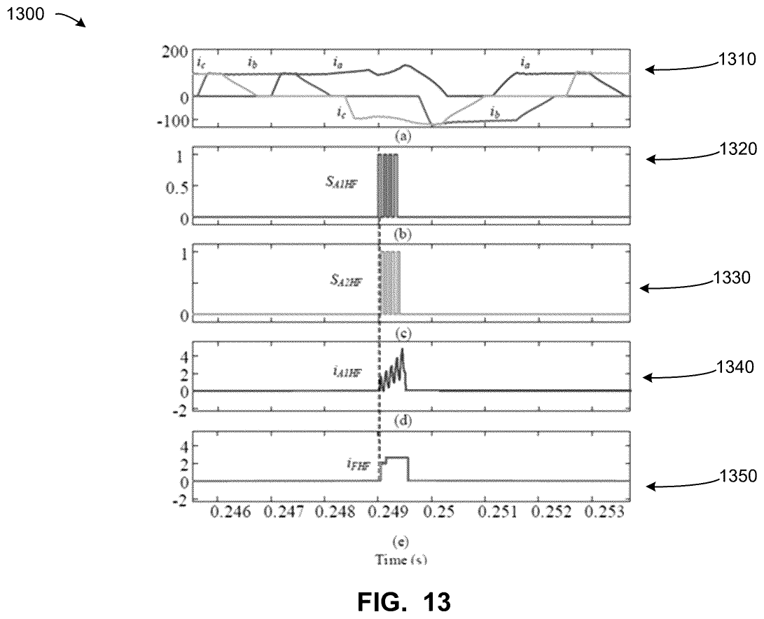

Reference is made to FIG. 13, which illustrates example simulation waveforms 1300 generated by testing the diagnosis and tolerant control disclosed herein for a short-circuit fault in the second cell (A2), in accordance with an example embodiment.

Waveforms 1300 include a first waveform 1310 corresponding to three-phase currents, a second waveform 1320 corresponding to HF pulse injection into the first cell (A1), a third waveform 1330 corresponding to HF pulse injection into the second cell (A2), a fourth waveform 1340 corresponding to induced HF current and a fifth waveform 1350 corresponding to fault variable.

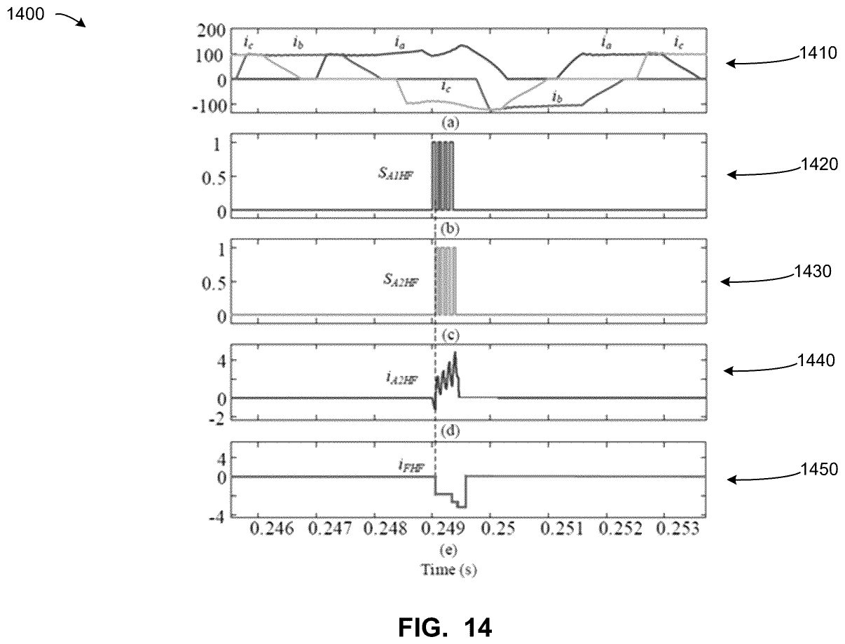

Reference is made to FIG. 14, which illustrates example simulation waveforms 1400 generated by testing the diagnosis and tolerant control disclosed herein for a short-circuit fault in the first cell (A1).

Waveforms 1400 include a first waveform 1410 corresponding to three-phase currents, a second waveform 1420 corresponding to HF pulse injection into the first cell (A1), a third waveform 1430 corresponding to HF pulse injection into the second cell (A2), a fourth waveform 1440 corresponding to induced HF current and a fifth waveform 1450 corresponding to fault variable.

As illustrated herein, short-circuit faults produce more obvious fault features as a short-circuit fault in a power switch causes continuous conduction irrespective of the control signals. A short-circuit fault, normally, produces a sudden current rise in the phase turn-on region crossing the threshold Is. Once the short-circuit fault is detected based on the process illustrated in FIG. 9, similar to open-circuit fault detection, the complementary HF pulses are injected into the power cells. Short-circuit fault in the first cell, A1, or the second cell, A2, is localized based on the status of the fault variable i_{FHF} as shown in FIG. 13 and FIG. 14. If i_{FHF} is negative, the short-circuit fault is located in the first cell A1 and if i_{FHF} is positive, the short-circuit fault is located in the second cell A2.

Numerous specific details are set forth herein in order to provide a thorough understanding of the exemplary embodiments described herein. However, it will be understood by those of ordinary skill in the art that these embodiments may be practiced without these specific details. In other instances, well-known methods, procedures and components have not been described in detail so as not to obscure the description of the embodiments. Furthermore, this description is not to be considered as limiting the scope of these embodiments in any way, but rather as merely describing the implementation of these various embodiments.

### ITEMS

Item 1. A method for a real-time diagnosis and tolerant control scheme for power switch open- and short-circuit faults in cascaded H-bridge (CHB) converter-fed SRM drives, comprising a). identifying the fault type within the CHB converter if its open or short circuit fault, b). localizing the power cell within the power converter where the identified fault has occurred; and c). remediating the identified faults.

Item 2. The method of any preceding item, utilizing the variation in fundamental current under an open or short-circuit fault for fault identification.

Item 3. The method of any preceding item, utilizing a phase-shifted high-frequency (HF) pulse that is injected into the power cells to localize the faulty power cell and consequently, the defective switch.

Item 4. The method of any preceding item, allowing the localization of the failure in the earliest stage locating a fault within a given sampling period.

Item 5. The method of any preceding item, utilizing only two switches within a power cell for current control due to the implementation of unipolar excitation making the remaining two switches in the power available as fault-tolerant auxiliary switches.

Item 6. The method of any preceding item for identifying open-circuit faults in a power cell system, utilizes only two diagonal switch pairs under normal operation that are excited alternatively in the two adjacent fundamental periods wherein if one pair of diagonal switches is found to be faulty, the switching signals are redirected to the other healthy pairs to continue machine operation enabling the SRM drive to maintain operation during open-circuit faults without reducing the drive system's performance, in contrast to traditional Medium Voltage (MV) drives.

Item 7. The method of any preceding item for identifying short-circuit faults in a power cell system, comprising a). remediating a single switch short-circuit fault without isolating the faulty cell through contactors; (b) identifying multiple short-circuit faults; and (c) utilizing a contactor to isolate the identified faulty cell.

1. A method for identifying and locating a fault condition in a cascaded H-bridge (CHB) converter system for driving a switched reluctance motor (SRM), the SRM comprising a predetermined number of phases (m), the CHB converter system comprising:
a plurality of cells arranged into m phase legs, each phase leg comprising a predetermined number (n) of cells cascaded in series, where n≥1, and wherein each phase leg corresponds to a respective phase winding of the SRM,
each cell comprising a plurality of switching elements and a corresponding dc-link, and
a controller configured to selectively control the switching elements of the cascaded cells of each phase leg to produce, at an output of the corresponding phase leg, a plurality of discrete phase voltage levels for operating the SRM in a plurality of operating modes, wherein the number of discrete phase voltage levels provided by each phase leg equals 2n+1, and
wherein the method comprises:
monitoring, for a selected phase leg, using the controller, a fundamental phase current;
determining, from the monitored current, a deviation indicative of a fault condition;
injecting complementary high-frequency (HF) diagnostic pulses into switching elements of different cells of the selected phase leg;
extracting a pulse-induced HF current component from the measured phase current;
determining, using the controller, a fault variable based on the extracted HF component; and
determining, from the fault variable, a location of a faulty cell within the selected phase leg.

2. The method of claim 1, wherein determining the deviation comprises classifying the fault condition as an open-circuit fault or a short-circuit fault based at least on the fundamental phase current and a predetermined reference current threshold.

3. The method of claim 2, wherein the fault condition is classified as an open-circuit fault if the fundamental phase current falls below the predetermined reference current threshold.

4. The method of claim 2, wherein the fault condition is classified as a short-circuit fault if the fundamental phase current increases above the predetermined reference current threshold.

5. The method of claim 1, further comprising remediating the fault condition.

6. The method of claim 1, wherein when the number of cells, n, per phase is equal to 2, the number of discrete phase voltage levels for each phase is 5.

7. The method of claim 6, wherein determining the location of the faulty cell comprises determining a short-circuit fault condition in an upper cell when, during positive excitation, the fault variable is less than zero.

8. The method of claim 6, wherein determining the location of the faulty cell comprises determining a short-circuit fault condition in a lower cell when, during positive excitation, the fault variable is greater than zero.

9. The method of claim 6, wherein determining the location of the faulty cell comprises determining a short-circuit fault condition in both an upper cell and a lower cell when, during positive excitation, the fault variable is approximately equal to zero.

10. The method of claim 6, wherein determining the location of the faulty cell comprises determining an open-circuit fault condition in an upper cell when the fundamental phase current is greater than an open-circuit current and the fault variable is less than zero.

11. The method of claim 6, wherein determining the location of the faulty cell comprises determining an open-circuit fault condition in a lower cell when the fundamental phase current is greater than an open-circuit current and the fault variable is greater than zero.

12. A system for identifying and locating a fault condition in a cascaded H-bridge (CHB) converter system for driving a switched reluctance motor (SRM), the SRM comprising a predetermined number of phases (m), the system comprising:
a plurality of cells arranged into m phase legs, each phase leg comprising a predetermined number (n) of cells cascaded in series, where n≥1, and wherein each phase leg corresponds to a respective phase winding of the SRM,
each cell comprising a plurality of switching elements and a corresponding dc-link, and
a controller configured to selectively control the switching elements of the cascaded cells of each phase leg to produce, at an output of the corresponding phase leg, a plurality of discrete phase voltage levels for operating the SRM in a plurality of operating modes, wherein the number of discrete phase voltage levels provided by each phase leg equals 2n+1,
wherein the controller is further configured to:
monitor, for a selected phase leg, a fundamental phase current;
determine, from the monitored current, a deviation indicative of a fault condition
inject complementary high-frequency (HF) diagnostic pulses into switching elements of different cells of the selected phase leg;
extract a pulse-induced HF current component from the measured phase current;
determine a fault variable based on the extracted HF component; and
determine, from the fault variable, a location of a faulty cell within the selected phase leg.

13. The system of claim 12, wherein the controller is configured to determine the deviation by classifying the fault condition as an open-circuit fault or a short-circuit fault based at least on the fundamental phase current and a predetermined reference current threshold.

14. The system of claim 13, wherein the fault condition is classified as an open-circuit fault if the fundamental phase current falls below the predetermined reference current threshold.

15. The system of claim 13, wherein the fault condition is classified as a short-circuit fault if the fundamental phase current increases above the predetermined reference current threshold.

16. The system of claim 12, wherein the controller is further configured to remediate the fault condition.

17. The system of claim 12, wherein when the number of cells, n, per phase is equal to 2, the number of discrete phase voltage levels for each phase is 5.

18. The system of claim 17, wherein the controller is configured to:
identify a short-circuit fault condition in an upper cell when, during positive excitation, the fault variable is less than zero, and
identify a short-circuit fault condition in a lower cell when, during positive excitation, the fault variable is greater than zero.

19. The system of claim 17, wherein the controller is configured to identify a short-circuit fault condition in both an upper cell and a lower cell when, during positive excitation, the fault variable is approximately equal to zero.

20. The system of claim 17, wherein the controller is configured to:
identify an open-circuit fault condition in an upper cell when the fundamental phase current is greater than an open-circuit current and the fault variable is less than zero, and
identify an open-circuit fault condition in a lower cell when the fundamental phase current is greater than an open-circuit current and the fault variable is greater than zero.
